(19) United States
(12) Patent Application Publication
(10) Pub. No.: US 2005/0249873 A1
(43) Pub. Date: Nov. 10, 2005

(54) Apparatuses and methods for producing chemically reactive vapors used in manufacturing microelectronic devices

(76) Inventors: Demetrius Sarigiannis, Medina, OH (US); Garo J. Derderian, Boise, ID (US)

Correspondence Address: PERKINS COIE LLP;PATENT-SEA, P.O. BOX 1247, SEATTLE, WA, 98111-1247, US

(21) Appl. No.: 10/839,316

(22) Filed: May 5, 2004

(51) Int. Cl. C23C 16/00

(52) U.S. Cl. 427/248.1; 118/715; 156/345.33

(57) ABSTRACT

Embodiments of the invention are directed to apparatuses and methods for producing chemical reactive vapors for vapor deposition processes, including chemical vapor deposition or atomic layer deposition processes used in manufacturing microfeature workpieces. In one embodiment, a gas is passed over a surface of a material in an ampoule to form a vapor in a vapor cell within the ampoule. The vapor cell has a volume, and the volume of the vapor cell is maintained at least approximately constant as the material is vaporized. In another embodiment, a gas is passed through an inlet of an ampoule and onto a surface of a material to form a vapor, and a distance between the inlet and the surface of the material is maintained approximately constant as the material is vaporized. In still other embodiments, the vapor produced by the foregoing embodiments is used in a vapor deposition process.

### TECHNICAL FIELD

The present invention relates to apparatuses and methods for producing chemically reactive vapors for chemical vapor deposition, atomic layer deposition, or other types of vapor deposition/etching processes used in manufacturing microelectronic devices.

### BACKGROUND

Thin film deposition techniques are widely used in the manufacturing of microfeatures to form a coating on a workpiece that closely conforms to the surface topography. The size of the individual components in the workpiece is constantly decreasing, and the number of layers in the workpiece is increasing. As a result, both the density of components and the aspect ratios of depressions (i.e., the ratio of the depth to the size of the opening) are increasing. Thin film deposition techniques accordingly strive to produce highly uniform conformal layers that cover the sidewalls, bottoms, and corners in deep depressions that have very small openings.

One widely used thin film deposition technique is Chemical Vapor Deposition (CVD). In a CVD system, one or more precursors that are capable of reacting to form a solid thin film are mixed while in a gaseous or vaporous state, and then the precursor mixture is presented to the surface of the workpiece. The surface of the workpiece catalyzes the reaction between the precursors to form a solid thin film at the workpiece surface. A common way to catalyze the reaction at the surface of the workpiece is to heat the workpiece to a temperature that causes the reaction.

Although CVD techniques are useful in many applications, they also have several drawbacks. For example, if the precursors are not highly reactive, then a high workpiece temperature is needed to achieve a reasonable deposition rate. Such high temperatures are not typically desirable because heating the workpiece can be detrimental to the structures and other materials already formed on the workpiece. Implanted or doped materials, for example, can migrate within the silicon substrate at higher temperatures. On the other hand, if more reactive precursors are used so that the workpiece temperature can be lower, then reactions may occur prematurely in the gas phase before reaching the substrate. This is undesirable because the film quality and uniformity may suffer, and also because it limits the types of precursors that can be used.

Atomic Layer Deposition (ALD) is another thin film deposition technique. In ALD processes, a layer of gas molecules from a first precursor gas coats the surface of a workpiece. The layer of first precursor molecules is formed by exposing the workpiece to the first precursor gas and then purging the chamber with a purge gas to remove excess molecules of the first precursor. This process can form a monolayer of first precursor molecules on the surface of the workpiece because the molecules at the surface are held in place during the purge cycle by physical adsorption forces at moderate temperatures or chemisorption forces at higher temperatures. The layer of first precursor molecules is then exposed to a second precursor gas. The first precursor molecules react with the second precursor molecules to form an extremely thin layer of material on the workpiece. The chamber is then purged again with a purge gas to remove excess molecules of the second precursor gas.

The precursor gases for CVD and ALD processes are generally produced by vaporizing a precursor using bubblers (i.e., ampoules with dip-tubes) or ampoules without dip-tubes. A typical bubbler introduces a carrier gas through a dip-tube having an outlet below the surface level of a liquid precursor so that the carrier gas rises through the precursor. As the gas rises through the liquid precursor, molecules of the precursor vaporize and are entrained in the flow of the carrier gas.

Ampoules without dip-tubes pass a carrier gas over the surface of a precursor without bubbling the carrier gas through the precursor. FIG. 1 is a cross-sectional side view of a typical ampoule 5 without a dip-tube in accordance with the prior art. The ampoule 5 includes a container 10 configured to contain a liquid 12 having a surface 14. The ampoule 5 also includes a headspace 30 above the surface 14 and an inlet tube 20 through which a carrier gas 18 flows into the headspace 30 and over the surface 14. The carrier gas 18 vaporizes the liquid 12 at the surface 14 to form a vapor 19 that exits the container 10 through an outlet 24.

One challenge in vapor deposition processes is to maintain a desired concentration of the precursor and carrier gas in the vapor. The concentration of the precursor in the vapor can fluctuate over time and significantly affect the quality of the film deposited in a vapor deposition process. The fluctuations in the precursor concentration can be caused by fluctuations in the evaporation rate. Therefore, it would be desirable to accurately control the evaporation rate of the precursor.

Another challenge in producing vapor in certain vapor deposition processes is producing a sufficient quantity of the precursor to provide a desired throughput (e.g., number of workpieces processed in a given period of time). More specifically, it is particularly difficult to produce a sufficient quantity of low vapor pressure precursors for maintaining an acceptable throughput. One solution for increasing the quantity of low vapor pressure precursors is to increase the flow rate of the carrier gas through the ampoule. Although this increases the vaporization rate of the precursor to produce more precursor in a given time period, the increased flow rate of the carrier gas also reduces the concentration of the precursor. In several instances, the reduced concentration of a low vapor pressure precursor is insufficient for producing a high quality film.

### BRIEF DESCRIPTION OF THE DRAWINGS

FIG. 1 is a cross-sectional side view of a vapor production apparatus in accordance with the prior art.

FIG. 2A is a cross-sectional side view of a vapor production apparatus with a control element in accordance with an embodiment of the invention.

FIG. 2B is a cross-sectional plan view of the vapor production apparatus of FIG. 2A taken along line 2B-2B.

FIG. 2C is a cross-sectional side view of the vapor production apparatus of FIG. 2A after some of the material has evaporated.

FIG. 3 is a cross-sectional side view of a vapor production apparatus with a float in accordance with another embodiment of the invention.

FIG. 4 is a cross-sectional side view of a vapor production apparatus with a support in accordance with a further embodiment of the invention.

FIG. 5 is a cross-sectional side view of a vapor production apparatus with a support in accordance with still another embodiment of the invention.

FIG. 6 is a cross-sectional side view of a vapor production apparatus with a valve in accordance with yet another embodiment of the invention.

FIG. 7 is a cross-sectional side view of a vapor production apparatus with a plunger in accordance with a further embodiment of the invention.

FIG. 8 is a cross-sectional side view of a vapor production apparatus with a plunger in accordance with still a further embodiment of the invention.

FIG. 9 is a partially schematic view of a vapor deposition system in accordance with still another embodiment of the invention.

### DETAILED DESCRIPTION

A. Overview

The following disclosure describes several embodiments of the present invention that are directed towards apparatuses and methods for producing vapors used in vapor deposition processes to fabricate microfeature devices. In particular, many specific details of the invention are described below with reference to single-wafer reactors for depositing material onto microfeature workpieces, but several embodiments can be used in batch systems for processing a plurality of workpieces simultaneously. Moreover, several embodiments can be used for depositing material onto workpieces other than microfeature workpieces. The term “microfeature workpiece” is used throughout to include substrates upon which and/or in which microelectronic devices, micromechanical devices, data storage elements, read/write components, and other features are fabricated. For example, microfeature workpieces can be semiconductor wafers such as silicon or gallium arsenide wafers, glass substrates, insulative substrates, and many other types of materials. Furthermore, the term “gas” is used throughout to include any form of matter that has no fixed shape and will conform in volume to the space available, which specifically includes vapors (i.e., a gas having a temperature less than the critical temperature so that it may be liquefied or solidified by compression at a constant temperature).

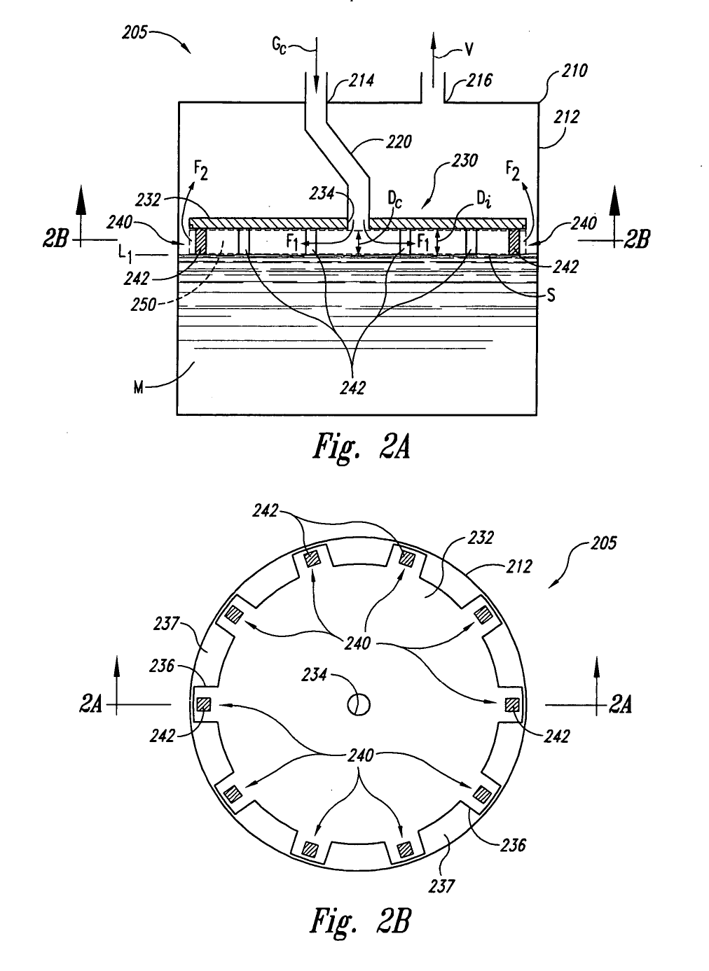

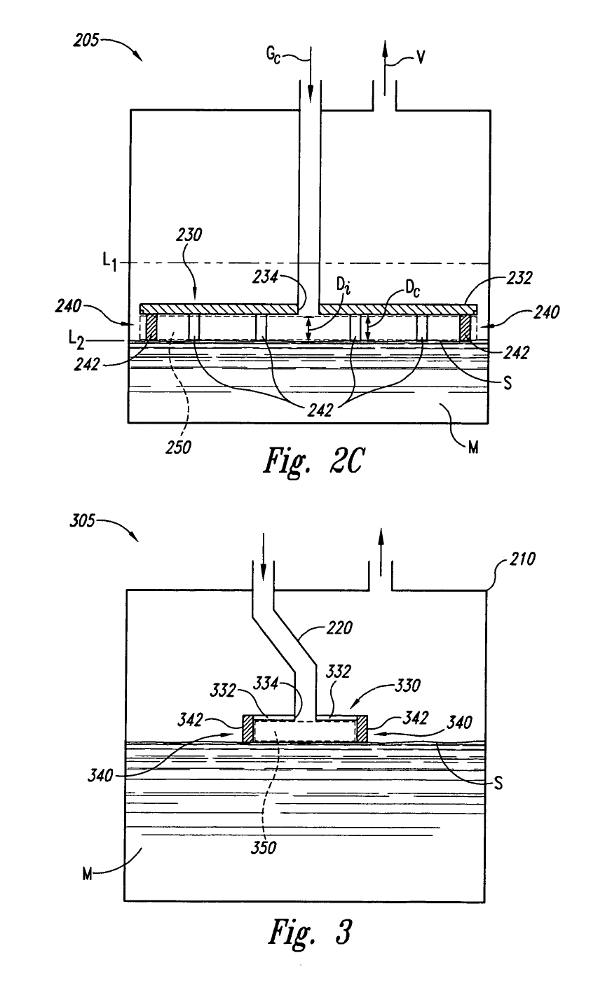

Several embodiments in accordance with the invention are set forth in FIGS. 2A-9 and the following text to provide a thorough understanding of particular embodiments of the invention. A person skilled in the art will understand, however, that the invention may have additional embodiments, or that the invention may be practiced without several of the details of the embodiments shown in FIGS. 2A-9.

One aspect of the invention is directed toward processes for producing a vapor. For example, an embodiment of a vapor production process includes passing a gas against a surface of a material in a vapor cell that is located within an ampoule. The vapor cell has a volume, and the method further includes maintaining the volume of the vapor cell at least approximately constant as the material is vaporized. Another embodiment of a method for producing vapor comprises passing a gas through an inlet of an ampoule onto a surface of a material in the ampoule to form a vapor. The method further includes maintaining a distance between the inlet and the surface of the material approximately constant as the material is vaporized.

Another aspect of the invention is directed toward vapor production systems. In one embodiment, a vapor production system comprises an ampoule configured to contain a material and a vapor cell in the ampoule. The vapor cell has an inlet through which a carrier gas passes to contact a surface of the material. The vapor production system also has a control mechanism configured to control the vapor cell and/or the material so that a distance between the gas inlet and the surface level of the material is maintained approximately constant as the material vaporizes. For example, a particular embodiment of the vapor cell includes a moveable inlet that moves relative to a level of the material as the material vaporizes.

Additional aspects of the invention are directed to vapor deposition systems comprising any of the foregoing vapor production systems operatively coupled to a vapor deposition chamber. The vapor deposition chamber receives vapor from the ampoule and distributes the vapor with respect to the workpiece support. As such, the vapor deposition chamber can include a workpiece support and a vapor distributor.

B. Embodiments of Vapor Production Methods and Systems

FIG. 2A is a cross-sectional side view and FIG. 2B is a cross-sectional plan view of a vapor production apparatus 205 in accordance with an embodiment of the invention. More particularly, FIG. 2A is a cross-section along line 2A-2A in FIG. 2B, and FIG. 2B is a cross-section along line 2B-2B in FIG. 2A. The vapor production apparatus 205 includes an ampoule 210 configured to contain a reactant or other material M (e.g., a liquid or solid precursor). The ampoule 210 is generally a sealed container or vessel having walls 212, an ampoule inlet 214 through which a carrier gas G_{c} flows into the ampoule 210, and an outlet 216 through which a vapor V flows out of the ampoule 210. The apparatus 205 also includes a moveable conduit 220, a vapor cell 230 in the ampoule 210 coupled to the moveable conduit 220, and a control mechanism 240 configured to control the vapor cell 230. In this embodiment, the control mechanism 240 controls the vapor cell 230 so that a headspace volume 250 defined by the vapor cell 230 remains approximately constant while the carrier gas G_{c} interfaces with the material M to produce a vapor with a consistent concentration of the material M and at a high vaporization rate.

The embodiment of the vapor cell 230 shown in FIGS. 2A-B includes a cover 232 having an inlet 234 coupled to the moveable conduit 220. The moveable conduit 220 can be a hose or other component that flexes, pivots or otherwise moves to allow the cover 232 to move along the walls 212 of the ampoule 210. The inlet 234 directs the flow of the carrier gas G_{c} into the headspace volume 250 under the cover 232. In this embodiment, the cover 232 is a plate or panel having a plurality of tabs 236 (FIG. 2B) and vents 237 (FIG. 2B). The tabs 236 can project radially outward to guide the cover 232 along the wall 212 of the ampoule 210. The cover 232 is generally formed from a material that is compatible with the precursor material, vapor and ampoule. For example, the cover 232 can be formed from high density polymers, certain metals, or other suitable materials.

The embodiment of the control mechanism 240 shown in FIGS. 2A-B includes a plurality of control elements 242 (e.g., floats or spacers) that support the cover 232 so that the cover 232 and the inlet 234 are spaced apart from the surface S of the material M by a distance D_{c} and a distance Dᵢ respectively. In some embodiments, the distance D_{c} and the distance Dᵢ can be approximately equal. In other embodiments, the distance D_{c} and the distance Dᵢ can be different.

In this embodiment, the control elements 242 are attached to the underside of the tabs 236. When the material M is a liquid, the control elements 242 can be floats that hold the cover 232 apart from the surface S by approximately the distance D_{c} (i.e., headspace) as the material M evaporates and the level of the surface S drops. The control elements 242 can accordingly be discrete blocks of open cell foams, inflatable tubes or other items that can support the cover 232 above the material M.

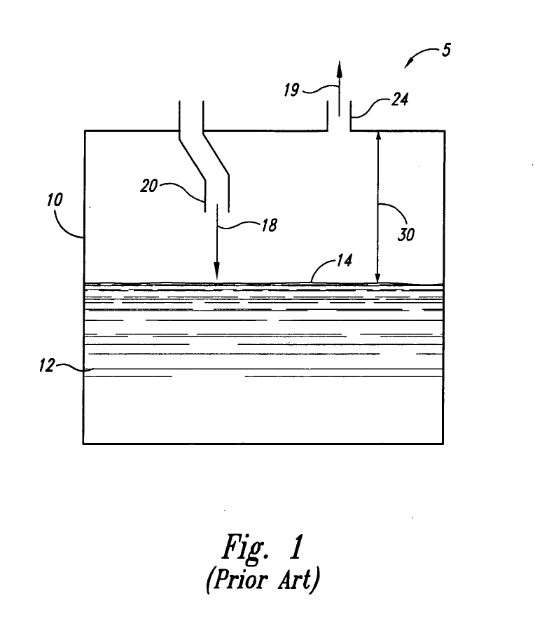

The embodiment of the vapor production apparatus 205 shown in FIG. 2A produces the vapor V by flowing the carrier gas G_{c} through the conduit 220 and the inlet 234 to produce a lateral flow F₁ of carrier gas across the surface S of the material M. The cover 232 directs the lateral flow F₁ of the carrier gas G_{c} radially outward toward the wall 212 so that the material M at the surface S vaporizes and is entrained in the lateral flow F₁. The vents 236 in the cover 232 direct an exit flow F₂ to the outlet 216 of the ampoule 210. The size of the cover 232 (e.g., the diameter) and the flow rate of the carrier gas G_{c} control the interaction between the carrier gas G_{c} and material M at the surface S to control the concentration of the material M in the vapor V. For example, the embodiment of the cover 232 shown in FIGS. 2A-B produces a higher concentration of the material M compared to a cover with a smaller diameter or just an inlet tube without a cover (i.e., inlet tube 20 in FIG. 1) because the lateral flow F₁ of the carrier gas G_{c} contacts a larger surface area of the surface S.

FIG. 2C is cross-sectional side view taken along line 2A-2A in FIG. 2B showing another aspect of operating this embodiment of the vapor production apparatus 205. More specifically, FIG. 2C shows the level of the surface S at a later time after a portion of the material M has evaporated. The surface S accordingly drops from a first level L₁ at a first period (shown in FIG. 2A) to a second level L₂ at a second period (shown in FIG. 2C). As the level of the surface S changes, the control elements 242 travel with the surface S so that the distance D_{c} between the cover 232 and the surface S remains at least approximately constant from the first period to the second period. The control mechanism 240 accordingly maintains the headspace volume 250 of the vapor cell 230 substantially constant while producing the vapor V. As described in more detail below, by maintaining a constant distance Dᵢ between the inlet 234 and the surface S, and by maintaining a constant headspace volume 250, the vapor cell 230 provides the ability to accurately control the concentration of the material M in the vapor V over a long period of time.

One feature of the embodiments of the vapor production apparatuses 205 shown in FIG. 2A-B and the associated methods of operation is that the distance Dᵢ between the inlet 234 and the surface S of the material M can remain approximately constant as the material M evaporates during the vapor production process. The interface between the flow of carrier gas G_{c} remains the same as the level of the material M drops, which results in a substantially constant evaporation rate of the material M. The concentration of material M in the vapor V is accordingly approximately constant over time as the material M evaporates. An advantage of this feature is that the concentration of precursor in the vapor V can be accurately controlled and held constant over time. This improves the consistency and quality of the film deposited during a vapor deposition process compared to the vapor produced by the vapor production process shown in FIG. 1.

Another feature of the vapor production apparatuses and methods described above with respect to FIGS. 2A-B is that the cover 232 contains the lateral flow F₁ of the carrier gas G_{c} proximate to more area across the surface S of the material M compared to the inlet tube 20 of the prior art device shown in FIG. 1. For a constant flow rate of carrier gas G_{c}, the concentration of the material M is much higher in the vapor production apparatus 205 as compared to the ampoule 5 shown in FIG. 1. The vapor production apparatus 205 accordingly enables the production of high concentration vapors with relatively lower flow rates. This feature is particularly useful in applications involving low vapor pressure precursors because the flow rate of carrier gas can be within an acceptable range and the vaporization rate can be sufficiently high to produce an adequate concentration of the low vapor pressure material in the vapor. Additionally, the higher vaporization rate can enable higher throughput and lower consumption of carrier gas.

The embodiments of the apparatus 205 and associated methods of operation described above with respect to FIGS. 2A-B can be modified in additional embodiments of the invention. For example, the tabs 236 and vents 237 can have different configurations, or these components can be eliminated such that the perimeter of the cover 232 is a circle or other shape. Additional alternative embodiments can have different control elements 242. For example, instead of having a plurality of control elements, the control mechanism 240 can have a single control element. Such a single control element can be an annular float with apertures through which the lateral flow of carrier gas can exit from the vapor cell. Several other embodiments of vapor production apparatuses and methods in accordance with the invention are described below with reference to FIGS. 3-8, and many of these alternative embodiments may have the same advantages as described above with reference to FIGS. 2A-B.

C. Additional Embodiments of Vapor Production Apparatuses

FIG. 3 illustrates a vapor production apparatus 305 in accordance with another embodiment of the invention. The apparatus 305 includes the ampoule 210 and moveable conduit 220. The apparatus 305 also includes a vapor cell 330 and a control mechanism 340. The vapor cell 330 has a cover element 332 and an inlet 334 at the end of the moveable conduit 220. The cover element 332, for example, can be spokes projecting from the lower end of the conduit 220. The control mechanism 340 in this embodiment is a single control element 342, such as an annular float, connected to the cover elements 332. The vapor cell 330 accordingly defines a headspace volume 350.

The vapor production apparatus 305 described above maintains the distance between the inlet 334 and the surface S of the material M approximately constant as the material M evaporates. Because this distance remains approximately constant, the concentration of precursor in the vapor can remain approximately constant over time as the material M evaporates. Thus, as described above with respect to FIGS. 2A-2C, an advantage of this feature is that the concentration of precursor in the vapor can be controlled.

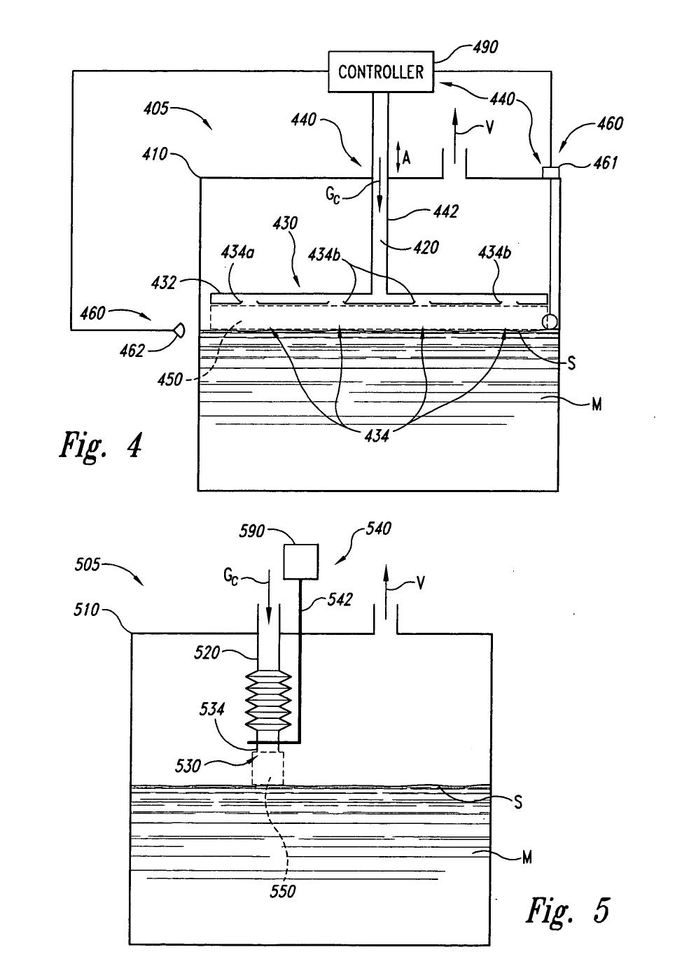

FIG. 4 is a cross-sectional view of a vapor production apparatus 405 in accordance with another embodiment of the invention. The apparatus 405 includes an ampoule 410, a vapor cell 430, and a control mechanism 440. The vapor cell 430 has a cover 432 with a plurality of inlets 434. Four inlets 434 are shown in FIG. 4, as a first inlet 434a and three second inlets 434b. Other embodiments can have more or fewer inlets 434.

The embodiment of the control mechanism 440 shown in FIG. 4 has one or more sensors 460, a controller 490 operatively coupled to the sensors 460, and a control element 442 coupled to the controller 490. In FIG. 4, two sensors 460 are shown as an internal sensor 461 and an external sensor 462, but only one of these sensors may be present in other embodiments. The sensors 460 can include optical-based systems and/or float systems that monitor the level of the material M in the ampoule 410. The controller 490 receives signals from the sensors 460 and moves the control element 442 (arrow A) to raise/lower the cover 432. The control element 442 has a conduit 420 through which the carrier gas G_{c} can flow to the inlets 434.

In operation, the carrier gas G_{c} passes through the moveable conduit 420, through a portion of the cover 432, out of the inlets 434, and over the surface S of the material M, producing a vapor V. As the material M evaporates, the level of the material M in the ampoule 410 drops, and the sensors 460 send signals to the controller 490 corresponding to the level of the surface S of the material M. The controller 490 moves the control element 442 so that the distance between the inlets 434 and the surface S of the material M, along with the headspace volume 450 of the vapor cell 430, remain approximately constant. Accordingly, embodiments of the invention discussed above with reference to FIG. 4 have advantages similar to those discussed with reference to FIGS. 2A-C.

The embodiments of the apparatus 405 and associated methods of operation described above with respect to FIG. 4 can be modified in additional embodiments of the invention. For example, each inlet 434 can have a different height above the surface S of the material M, but the distance between each inlet 434 and the surface S can be maintained approximately constant by the control mechanism 440. In another embodiment, the apparatus 405 can include a first support that supports the inlets 434 and a second support that supports the cover 432. In some embodiments, as shown in FIG. 4, the control element 442 can include the moveable conduit 420, while in other embodiments the moveable conduit 420 can be separate from the control element 442. For example, the control element 442 can be a rod or shaft, and the moveable conduit 420 can be a separate flexible tube. In some embodiments, the controller 490 can be a computer-operated system having computer operable instructions that cause the controller 490 to raise/lower the cover and/or inlets in response to the signals from the sensors. In other embodiments, the sensors 460 can be coupled to a display and an operator can manually adjust the control mechanism 440. In still other embodiments, the control mechanism 440 can be adjusted manually by an operator without the use of sensors.

FIG. 5, illustrates a vapor production apparatus 505 in accordance with another embodiment of the invention. The apparatus 505 includes an ampoule 510 and a moveable conduit 520. The apparatus 505 also includes a vapor cell 530 under the conduit 520 and a control mechanism 540 coupled to the conduit 520. The vapor cell 530 includes an inlet 534 at the end of the moveable conduit 520. The vapor cell 530 is, in part, a virtual cell under the inlet 534 that defines a headspace volume 550.

The control mechanism 540 includes a controller 590 and a control element 542. The control element 542, for example, can be a bracket or other type of support element that supports the inlet 534. The controller 590 adjusts the position of the control element 542 to maintain the distance between the inlet 534 and the surface S of the material M approximately constant as the material M evaporates. Because this distance remains approximately constant, the concentration of precursor in the vapor is expected to remain approximately constant over time as the material M evaporates. Thus, as described above with respect to FIGS. 2A-2C, an advantage of this feature is that the concentration of precursor in the vapor can be controlled.

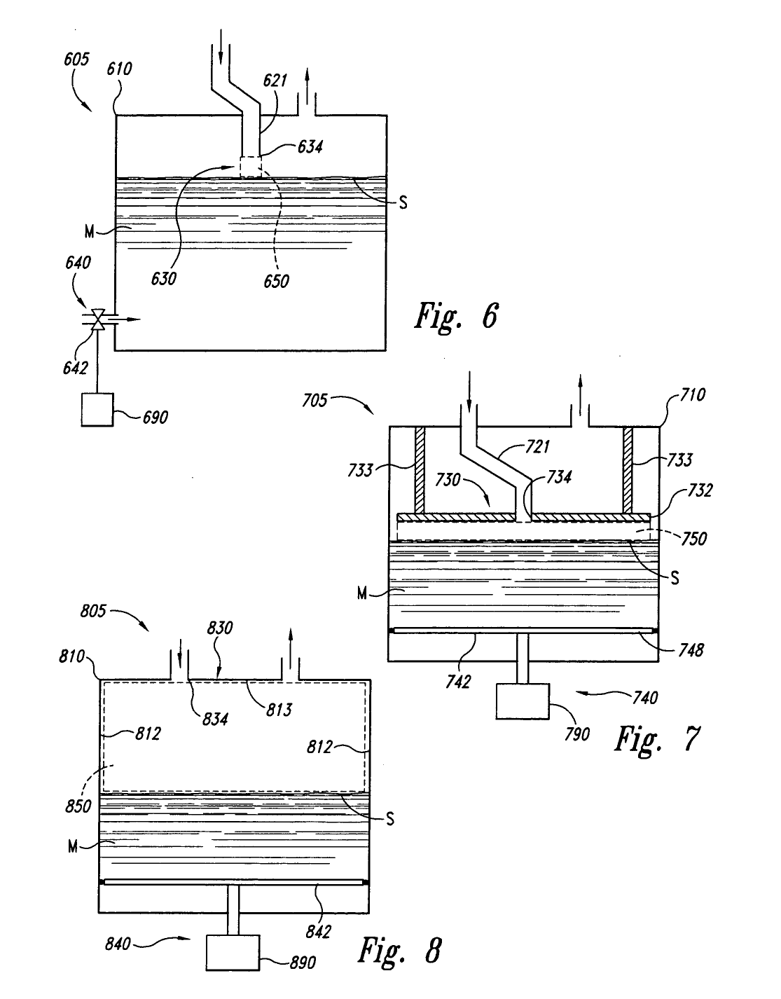

FIG. 6 is a cross-sectional view of a vapor production apparatus 605 in accordance with another embodiment of the invention. The apparatus 605 includes an ampoule 610 and a fixed conduit 621. The apparatus 605 also includes a vapor cell 630 and a control mechanism 640. The vapor cell 630 includes an inlet 634 at the end of the fixed conduit 621. The vapor cell 630 accordingly defines a headspace volume 650.

The control mechanism 640 includes a controller 690 and a control element 642. In this embodiment, the control element 642 is a valve that controls a flow of the material M to enter the ampoule. The controller 690 adjusts the control element 642 to inject additional material M into the ampoule 610 to replace the material M that evaporates during the vapor production process. The flow rate of the material M is set to approximate the evaporation rate to maintain the distance between the inlet 634 and the surface S of the material M approximately constant. Because this distance remains approximately constant, the concentration of precursor in the vapor can remain approximately constant over time as the material M evaporates. Thus, as described above with respect to FIGS. 2A-2C, an advantage of this feature is that the concentration of precursor in the vapor can be controlled.

FIG. 7, illustrates a vapor production apparatus 705 in accordance with another embodiment of the invention. The apparatus 705 includes an ampoule 710, a fixed conduit 721, a vapor cell 730, and a control mechanism 740. The vapor cell 730 has a cover 732, which is supported in a fixed position by two fixed supports 733. Other embodiments can have more or fewer supports 733 and/or other support arrangements. The vapor cell 730 also has an inlet 734 in the cover 732 at the end of the fixed conduit 721. The vapor cell 730 accordingly defines a headspace volume 750.

The control mechanism 740 includes a controller 790 and a control element 742. The control element 742 in FIG. 7 is a moveable plunger that displaces material M in the ampoule. In operation, the controller 790 raises the control element 742 as the material M evaporates to maintain the distance between the inlet 734 and the surface S of the material M approximately constant. The headspace volume 750 also remains approximately constant. Accordingly, embodiments of the invention discussed above with reference to FIG. 7 have advantages similar to those discussed with reference to FIGS. 2A-C.

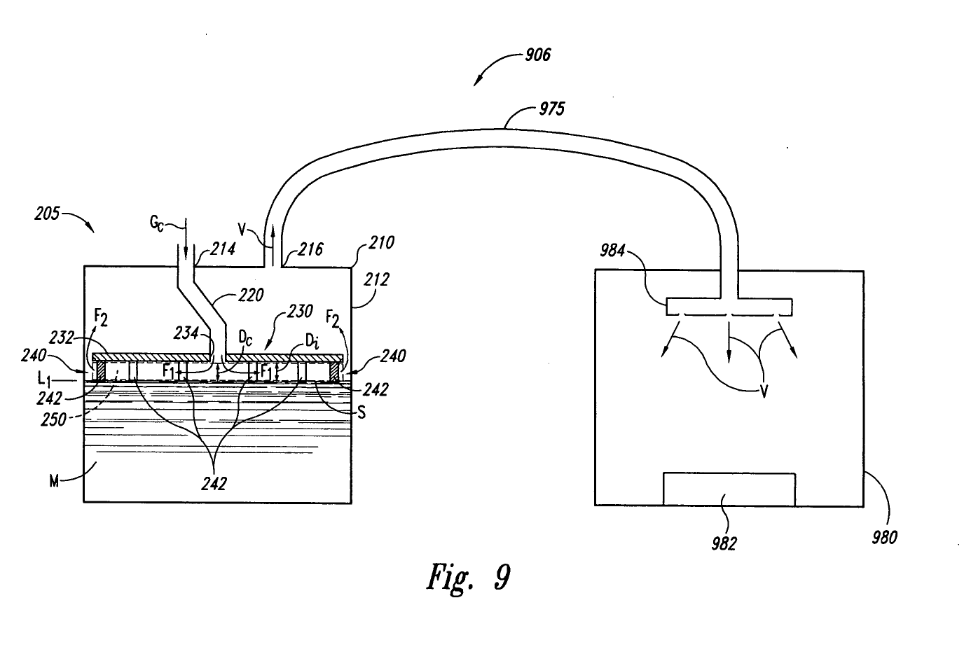

FIG. 8 is a cross-sectional view of a vapor production apparatus 805 in accordance with another embodiment of the invention. The apparatus 805 includes an ampoule 810, a vapor cell 830, and a control mechanism 840. The vapor cell 830 includes a portion of the walls 812 of the ampoule, a portion of the ceiling 813 of the ampoule, and an inlet 834. The vapor cell 830 accordingly defines a headspace volume 850.

The control mechanism 840 includes a controller 890 and a control element 842. The control element 842 includes a moveable plunger that displaces material M in the ampoule. As discussed above with reference to FIG. 7, the controller 890 moves the control element 842 to displace the material M that evaporates to maintain the distance between the inlet 834 and the surface S of the material M, along with the headspace volume 850, approximately constant. Accordingly, embodiments of the invention discussed above with reference to FIG. 8 have advantages similar to those discussed with reference to FIGS. 2A-C.

D. Embodiments of Vapor Deposition Methods and Systems

FIG. 9 is a partially schematic view of a vapor deposition system 906 that includes the vapor production apparatus 205, shown in FIG. 2A, and a vapor deposition chamber 980. Like reference numbers refer to like elements in FIG. 2A and FIG. 9. The vapor V, produced in the vapor production apparatus 205, passes through a passage 975 to the deposition chamber 980. The passage 975 generally has a valve system coupled to a controller to control the flow of the vapor V to the deposition chamber 980. The deposition chamber 980 includes a workpiece support 982 and a vapor distributor 984 that disperses the vapor V relative to the workpiece support 982. Accordingly, the vapor V can deposit a film on a microfeature workpiece supported by the workpiece support 982.

As discussed above, the apparatus 205 maintains the distance Dᵢ between the inlet 234 and the surface S of the material M, along with the headspace volume 250, approximately constant. This provides a consistent concentration of precursor, in a desired quantity, to the deposition chamber 980. Accordingly, embodiments of the invention discussed above with reference to FIG. 8 have advantages similar to those discussed with reference to FIGS. 2A-C. In other embodiments, different vapor production apparatuses or methods can be used to produce the vapor V, for example, apparatuses and methods described above with reference to FIGS. 3-8.

From the foregoing, it will be appreciated that specific embodiments of the invention have been described herein for purposes of illustration, but that various modifications may be made without deviating from the spirit and scope of the invention. For example, features described above in the context of particular embodiments can be combined or eliminated in other embodiments. Accordingly, the invention is not limited except as by the following claims.

1. In vapor deposition processing for fabricating microfeature devices, a method for producing vapor comprising:
passing a gas over a surface of a material in an ampoule to form a vapor in a vapor cell within the ampoule, wherein the vapor cell has a volume; and
maintaining the volume of the vapor cell at least approximately constant as the material is vaporized.

2. The method of claim 1, further comprising maintaining a distance between an inlet and the surface of the material at least approximately constant as the material is vaporized.

3. The method of claim 1 wherein maintaining the volume of the vapor cell at least approximately constant comprises adding material to the ampoule to compensate for vaporization of the material.

4. The method of claim 1 wherein maintaining the volume of the vapor cell at least approximately constant comprises using a plunger to displace material toward the vapor cell to compensate for vaporization of the material.

5. The method of claim 1 wherein the vapor cell has a head space defined by a cover supported by a float, the headspace being the distance between the surface of the material and the cover, and maintaining the volume of the vapor cell at least approximately constant comprises supporting the cover with the float above the surface of the material so that the headspace of the vapor cell remains at least approximately constant as the material vaporizes.

6. The method of claim 1 wherein the vapor cell has a headspace defined by a cover supported by a support, the headspace being the distance between the surface of the material and the cover, and maintaining the volume of the vapor cell at least approximately constant comprises adjusting the support to maintain the headspace of the vapor cell at least approximately constant as the material vaporizes.

7. A method for producing vapor comprising:
passing a gas through an inlet of an ampoule and onto a surface of a material in the ampoule to form a vapor; and
maintaining a distance between the inlet and the surface of the material approximately constant as the material is vaporized.

8. The method of claim 7 wherein maintaining the distance between the inlet and the surface of the material approximately constant comprises adding material to the ampoule to compensate for evaporation of the material.

9. The method of claim 7 wherein at least a portion of the ampoule has a vapor cell with a headspace, the headspace being the distance between the surface of the material and a surface above the material, and wherein maintaining the distance between the inlet and the surface of the material approximately constant comprises adding material to the ampoule to compensate for evaporation of the material and further comprising maintaining the headspace of at least a portion of a vapor cell approximately constant by adding material to the ampoule to compensate for evaporation of the material.

10. The method of claim 7 wherein maintaining the distance between the inlet and the surface of the material approximately constant comprises using a plunger to displace material toward the inlet to compensate for evaporation of the material.

11. The method of claim 7 wherein at least a portion of the ampoule has a vapor cell with a headspace, the headspace being the distance between the surface of the material and a surface above the material, and wherein maintaining the distance between the inlet and the surface of the material approximately constant comprises using a plunger to displace material toward the inlet to compensate for evaporation of the material and further comprising maintaining the headspace of at least a portion of a vapor cell approximately constant by using a plunger to displace material toward the surface above the material to compensate for evaporation of the material.

12. The method of claim 7 wherein the inlet is a moveable conduit having a float configured to support the inlet at the distance above the surface and maintaining the distance between the inlet and the surface of the material approximately constant comprises supporting the inlet with the float above the surface of the material.

13. The method of claim 7 wherein the inlet is a moveable conduit having a float configured to support the inlet at the distance above the surface, the float being further configured to support a cover, the cover creating a vapor cell with a headspace in at least a portion of the ampoule, the headspace being the distance between the surface of the material and the cover, and maintaining the distance between the inlet and the surface of the material approximately constant comprises supporting the inlet with the float above the surface of the material, and further comprising maintaining the headspace of at least a portion of a vapor cell approximately constant by supporting the cover with the float above the surface of the material.

14. The method of claim 7, further comprising supporting the inlet above the surface of the material with an adjustable support and wherein maintaining the distance between the inlet and the surface of the material approximately constant comprises adjusting the support.

15. The method of claim 7, further comprising:
supporting the inlet above the surface of the material with an adjustable support and wherein maintaining the distance between the inlet and the surface of the material approximately constant comprises adjusting the support;
supporting a cover above the surface of the material with the support; and
defining a headspace for at least a portion of a vapor cell with the cover, the headspace being the distance between the surface of the material and the cover.

16. The method of claim 7 wherein passing the gas through the inlet includes passing the gas through a first inlet, and further comprising passing the gas through at least a second inlet.

17. The method of claim 7, further comprising sensing a level of the material and wherein maintaining the distance between the inlet and the surface of the material approximately constant comprises using the level of the material to adjust the distance between the inlet and the surface of the material.

18. A vapor production apparatus for producing vapor for a vapor deposition process for fabricating microfeature devices comprising:
an ampoule configured to contain a material;
a vapor cell in the ampoule, the vapor cell having an inlet through which a gas passes to a surface level of the material; and
a control mechanism configured to control the vapor cell and/or the material so that a distance between the gas inlet and the surface level of the material is maintained approximately constant as the material vaporizes.

19. The system of claim 18, further comprising a moveable conduit coupled to the inlet.

20. The system of claim 18 wherein the control mechanism comprises a valve that is configured to add material to the ampoule.

21. The system of claim 18 wherein the control mechanism comprises a plunger configured to displace material so that the distance between the gas inlet and the surface level of the material is maintained approximately constant as the material vaporizes.

22. The system of claim 18 wherein the inlet is a moveable conduit and the control mechanism comprises a float configured to support the inlet at the distance above the surface.

23. The system of claim 18 wherein the inlet is a moveable conduit and the control mechanism comprises a float configured to support the inlet at the distance above the surface and wherein the float is further configured to support a cover, the cover defining a headspace of the vapor cell, the headspace being the distance between the surface level of the material and the cover.

24. The system of claim 18 wherein the inlet is moveable and the control mechanism comprises a support configured to support the inlet at the distance above the surface.

25. The system of claim 18 wherein the inlet is moveable and the control mechanism comprises a support configured to support the inlet at the distance above the surface and wherein the support is further configured to support a cover, the cover defining a headspace of the vapor cell, the headspace being the distance between the surface level of the material and the cover.

26. The system of claim 18 wherein the inlet includes a first inlet, and further comprising at least a second inlet.

27. The method of claim 18, further comprising a sensor configured to sense the surface level of the material, the surface level of the material being used to make adjustments to maintain the distance between the gas inlet and the surface level of the material is approximately constant as the material vaporizes.

28. A vapor production apparatus for producing vapor for a vapor deposition process for fabricating microfeature devices comprising:
an ampoule configured to contain a material; and
a vapor cell in the ampoule, the vapor cell including a moveable inlet that moves relative to a level of the material as the material vaporizes.

29. The system of claim 28 wherein the moveable inlet is a moveable conduit supported a distance above the level of the material by a float such that the float moves relative to the level of the material to maintain the inlet at approximately the distance above the level of the material as the material vaporizes.

30. The system of claim 28 wherein the moveable inlet is supported a distance above the level of the material by a support, the support being moveable relative to the level of the material to maintain the inlet at approximately the distance above the level of the material as the material vaporizes.

31. The system of claim 28 wherein the moveable inlet is a moveable conduit supported a distance above the level of the material by a float such that the float moves relative to the level of the material to maintain the inlet at approximately the distance above the level of the material as the material vaporizes, and further comprising a cover above the level of the material, the cover defining a headspace of the vapor cell, the headspace being a distance between the level of the material and the cover, the cover being supported by the float such that the float moves relative to the level of the material to maintain the headspace approximately constant as the material vaporizes.

32. The system of claim 28 wherein the moveable inlet is supported a distance above the level of the material by a support, the support being moveable relative to the level of the material to maintain the inlet at approximately the distance above the level of the material as the material vaporizes, and further comprising a cover above the level of the material, the cover defining a headspace of the vapor cell, the headspace being a distance between the level of the material and the cover, the cover being supported by the support, the support being moveable relative to the level of the material to maintain the headspace approximately constant as the material vaporizes.

33. A vapor production apparatus for producing vapor for a vapor deposition process for fabricating microfeature devices comprising:
an ampoule configured to contain a material;
a vapor cell in the ampoule, the vapor cell having an inlet through which a gas passes to a surface level of the material and a headspace, the headspace being a distance between a surface of the material and a surface above the material; and
a control mechanism configured to control the headspace of the vapor cell so that the headspace is maintained approximately constant as the material vaporizes.

34. The system of claim 33 wherein the control mechanism is further configured to maintain a distance between the inlet and the surface level of the material approximately constant as the material vaporizes.

35. The system of claim 33 wherein the control mechanism comprises a plunger configured to displace material toward the surface above the material so that the headspace is maintained approximately constant as the material vaporizes.

36. The system of claim 33 wherein the control mechanism comprises a valve configured to add material to the ampoule so that the headspace is maintained approximately constant as the material vaporizes.

37. The system of claim 33 wherein a cover is the surface above the material in the vapor cell and the control mechanism comprises a float configured to support the cover at the distance above the surface of the material such that the headspace is maintained approximately constant as the material vaporizes.

38. The system of claim 33 wherein a cover is the surface above the material in the vapor cell and the control mechanism comprises a support configured to support the cover at the distance above the surface of the material such that the headspace is maintained approximately constant as the material vaporizes.

39. A vapor production apparatus for producing vapor for a vapor deposition process for fabricating microfeature devices comprising:
an ampoule configured to contain a material;
a vapor cell in the ampoule, the vapor cell having a headspace, the headspace being the distance between a surface of the material and a cover, the vapor cell also having an inlet through which a gas passes to a surface of the material, the inlet comprising a moveable conduit; and
a float configured to support the inlet and the cover so that the headspace is maintained approximately constant as the material vaporizes.

40. A vapor deposition apparatus for forming a layer of material on a microfeature workpiece comprising:
an ampoule configured to contain a material;
a vapor cell in the ampoule, the vapor cell having an inlet through which a gas passes to a surface level of the material; and
a control mechanism configured to control the vapor cell and/or the material so that a distance between the gas inlet and the surface level of the material is maintained approximately constant as the material vaporizes; and
a vapor deposition chamber having a workpiece support and a vapor distributor operatively coupled to the ampoule to receive the vapor from the ampoule and distribute the vapor with respect to the workpiece support.

41. A vapor deposition apparatus for forming a layer of material on a microfeature workpiece comprising:
an ampoule configured to contain a material;
a vapor cell in the ampoule, the vapor cell including a moveable inlet that moves relative to a level of the material as the material vaporizes; and
a vapor deposition chamber having a workpiece support and a vapor distributor operatively coupled to the ampoule to receive the vapor from the ampoule and distribute the vapor with respect to the workpiece support.

42. A vapor deposition apparatus for forming a layer of material on a microfeature workpiece comprising:
an ampoule configured to contain a material;
a vapor cell in the ampoule, the vapor cell having an inlet through which a gas passes to a surface level of the material and a headspace, the headspace being a distance between a surface of the material and a surface above the material;
a control mechanism configured to control the headspace of the vapor cell so that the distance between a surface of the material and a surface above the material is maintained approximately constant as the material vaporizes; and
a vapor deposition chamber having a workpiece support and a vapor distributor operatively coupled to the ampoule to receive the vapor from the ampoule and distribute the vapor with respect to the workpiece support.
